(19) United States
(12) Patent Application Publication
(10) Pub. No.: US 2012/0213941 A1
(43) Pub. Date: Aug. 23, 2012

(54) ION-ASSISTED PLASMA TREATMENT OF A THREE-DIMENSIONAL STRUCTURE

(75) Inventors: Louis Steen, Atkinson, NH (US); Ludovic Godet, Boston, MA (US); Patrick M. Martin, Ipswich, MA (US)

(73) Assignee: VARIAN SEMICONDUCTOR EQUIPMENT ASSOCIATES, INC., Gloucester, MA (US)

(21) Appl. No.: 13/401,168

(22) Filed: Feb. 21, 2012

Related U.S. Application Data
(60) Provisional application No. 61/445,174, filed on Feb. 22, 2011.

(51) Int. Cl. C23C 16/50; B08B 7/00; C23C 16/02; C23C 16/52; C23C 16/06

(52) U.S. Cl. 427/535; 427/569; 427/8; 427/576; 134/1.1

(57) ABSTRACT

A boundary between a plasma and a plasma sheath is controlled such that a portion of the shape is not parallel to a plane defined by a front surface of the workpiece facing the plasma. Ions in the plasma are directed toward the workpiece. These ions can either seal pores or clean a material from a structure on the workpiece. This structure may, for example, have multiple sidewalls. A process that both cleans a material and seals pores in the structure may be performed.

### CROSS-REFERENCE TO RELATED APPLICATIONS

This application claims priority to the provisional patent application entitled “Three-Dimensional Ion Beam Assisted Pore Sealing,” filed Feb. 22, 2011 and assigned U.S. App. No. 61/445,174, the disclosure of which is hereby incorporated by reference.

### FIELD

This invention relates to three-dimensional structures and, more particularly, to ion-assisted plasma treatment of three-dimensional structures.

### BACKGROUND

Three-dimensional structures are used in the semiconductor industry for advanced interconnects in logic and memory chip fabrication. The material for these devices may be a porous dielectric material such as, for example, SiCOH. The porosity of this material is used to achieve the lowest capacitance of the structure, but these pores have drawbacks. First, the pores serve as traps for etch residue. Second, the pores allow moisture to penetrate the dielectric and lead to leakage or time dependent dielectric breakdown (TDDB) failures. Third, the pores have a negative effect on the uniform nucleation of the barrier metal and lead to point defects in the barrier metal or defects in the copper seed layer that reduce the reliability of the copper interconnect line. Sealing the pores prior to deposition of the barrier metal eliminates these problems. However, sealing pores on a three-dimensional surface is challenging. What are needed are an improved method of ion-assisted plasma treatment for three-dimensional structures and, more particularly, an improved method of pore sealing or cleaning for three-dimensional structures.

### SUMMARY

According to a first aspect of the invention, a method of workpiece processing is provided. The method comprises generating a plasma having a plasma sheath proximate a surface of the workpiece. The workpiece defines a structure with a plurality of sidewalls. A shape of a boundary between the plasma and the plasma sheath is controlled whereby a portion of the shape is not parallel to a plane defined by a front surface of the workpiece facing the plasma. The ions in the plasma are directed toward the workpiece. The pores on one of the sidewalls are sealed with the ions.

According to a second aspect of the invention, a method of workpiece processing is provided. The method comprises generating a plasma having a plasma sheath proximate a surface of the workpiece. The workpiece defines a structure with a plurality of sidewalls. A shape of a boundary between the plasma and the plasma sheath is controlled whereby a portion of the shape is not parallel to a plane defined by a front surface of the workpiece facing the plasma. The ions in the plasma are directed toward the workpiece. A material is removed from one of the sidewalls of the structure with the ions.

According to a third aspect of the invention, a method of workpiece processing is provided. The method comprises generating a first plasma having a first plasma sheath proximate a surface of the workpiece. The workpiece defines a trench with a plurality of sidewalls. A first shape of a first boundary between the first plasma and the first plasma sheath is controlled whereby a portion of the first shape is not parallel to a plane defined by a front surface of the workpiece facing the first plasma. The first ions in the first plasma are directed toward the workpiece. Etch residue is removed from one of the sidewalls of the trench with the first ions. A second plasma is generated having a plasma sheath proximate the surface. A second shape of a second boundary between the second plasma and the second plasma sheath is controlled whereby a portion of the second shape is not parallel to the plane. The second ions in the second plasma are directed toward the workpiece. Pores on one of the sidewalls are sealed with the second ions.

### BRIEF DESCRIPTION OF THE DRAWINGS

For a better understanding of the present disclosure, reference is made to the accompanying drawings, which are incorporated herein by reference and in which:

FIG. 1 is a block diagram of a plasma processing apparatus;

FIG. 2 is a block diagram of a plasma processing apparatus consistent with an embodiment of the disclosure;

FIG. 3 is a SEM photograph of a first three-dimensional structure;

FIG. 4 is a cross-sectional diagram of a second three-dimensional structure;

FIG. 5 illustrates a first embodiment of pore sealing;

FIG. 6 illustrates a second embodiment of pore sealing;

FIG. 7 illustrates a third embodiment of pore sealing;

FIGS. 8-10 illustrate a fourth embodiment of pore sealing; and

FIG. 11 illustrates a first embodiment of cleaning.

### DETAILED DESCRIPTION

These embodiments are described herein in connection with an ion implanter or plasma system. However, the embodiments can be used with other systems and processes involved in semiconductor manufacturing or other systems that use ions. Thus, the invention is not limited to the specific embodiments described below.

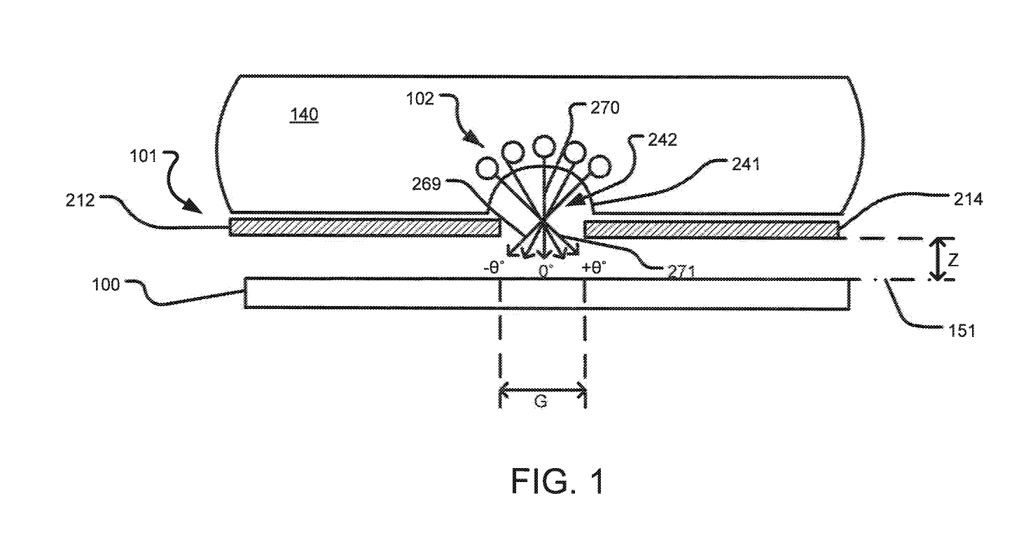

FIG. 1 is a block diagram of a plasma processing apparatus. The plasma 140 is generated as is known in the art. This plasma 140 is generally a quasi-neutral collection of ions and electrons. The ions typically have a positive charge while the electrons have a negative charge. The plasma 140 may have an electric field of, for example, approximately 0 V/cm in the bulk of the plasma 140. In a system containing the plasma 140, ions 102 from the plasma 140 are attracted toward a workpiece 100. These ions 102 may be attracted with sufficient energy to be implanted into the workpiece 100. The plasma 140 is bounded by a region proximate the workpiece 100 referred to as a plasma sheath 242. The plasma sheath 242 is a region that has fewer electrons than the plasma 140. Hence, the differences between the negative and positive charges cause a sheath potential in the plasma sheath 242. The light emission from this plasma sheath 242 is less intense than the plasma 140 because fewer electrons are present and, hence, fewer excitation-relaxation collisions occur. Thus, the plasma sheath 242 is sometimes referred to as “dark space.”

The sheath modifier 101 is configured to modify an electric field within the plasma sheath 242 to control a shape of a boundary 241 between the plasma 140 and the plasma sheath 242. Accordingly, ions 102 that are attracted from the plasma 140 across the plasma sheath 242 may strike the workpiece 100 at a large range of incident angles. This sheath modifier 101 also may he referred to as, for example, a focusing plate or sheath engineering plate and may be a semiconductor, insulator, or conductor.

In the embodiment of FIG. 1, the sheath modifier 101 includes a pair of panels 212 and 214 defining an aperture therebetween having a horizontal spacing (G). In other embodiments, the sheath modifier 101 may include only one panel or more than two panels. The panels 212 and 214 may be a pair of sheets having a thin, flat shape. In other embodiments, the panels 212 and 214 may be other shapes such as tube-shaped, wedge-shaped, and/or have a beveled edge proximate the aperture. The panels 212 and 214 also may be positioned a vertical spacing (Z) above the plane 151 defined by the front surface of the workpiece 100. In one embodiment, the vertical spacing (Z) may be about 1.0 to 10.0 mm.

Ions 102 may be attracted from the plasma 140 across the plasma sheath 242 by different mechanisms. In one instance, the workpiece 100 is biased to attract ions 102 from the plasma 140 across the plasma sheath 242. In another instance, a plasma source that generates the plasma 140 and walls surrounding the plasma 140 are biased positively and the workpiece 100 may be grounded. The biasing may be pulsed in one particular embodiment. In yet another instance, electric or magnetic fields are used to attract ions 102 from the plasma 140 toward the workpiece 100.

Advantageously, the sheath modifier 101 modifies the electric field within the plasma sheath 242 to control a shape of the boundary 241 between the plasma 140 and the plasma sheath 242. The boundary 241 between the plasma 140 and the plasma sheath 242 may have a convex shape relative to the plane 151 or another shape not parallel to the plane 151. When the workpiece 100 is biased, for example, the ions 102 are attracted across the plasma sheath 242 through the aperture between the panels 212 and 214 at a large range of incident angles. For instance, ions 102 following trajectory path 271 may strike the workpiece 100 at an angle of +θ° relative to the plane 151. Ions 102 following trajectory path 270 may strike the workpiece 100 at about an angle of 0° relative to the same plane 151. Ions 102 following trajectory path 269 may strike the workpiece 100 an angle of −θ° relative to the plane 151. Accordingly, the range of incident angles may be between +θ° and −θ° centered about 0°. In addition, some ion trajectories paths such as paths 269 and 271 may cross each other. Depending on a number of factors including, but not limited to, the horizontal spacing (G) between the panels 212 and 214, the vertical spacing (Z) of the panels 212 and 214 above the plane 151, the dielectric constant of the panels 212 and 214, or other process parameters of the plasma 140, the range of incident angles (θ) may be between +60° and −60° centered about 0°, though other ranges of θ are possible. In another embodiment, the panels 212 and 214 may each have different vertical spacing (Z) relative to the workpiece 100, which may allow the ions 102 to primarily follow trajectories at an angle relative to the plane 151.

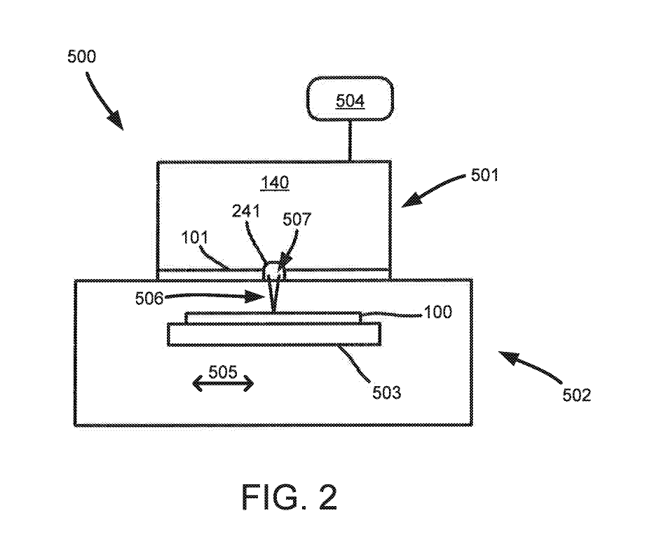

FIG. 2 is a block diagram of a plasma processing apparatus consistent with an embodiment of the disclosure. The system 500 includes a plasma source 501, a sheath modifier 101, and a process chamber 502. A gas source 504 is connected to the plasma source 501. The plasma source 501 or other components of the system 500 also may be connected to a pump, such as a turbopump. The plasma source 501 that generates the plasma 140 may be, for example, an RF plasma source, inductively-coupled plasma (ICP) source, indirectly heated cathode (IHC), capacitively-coupled plasma (CCP) source, helicon plasma source, microwave plasma source, or other plasma sources known to those skilled in the art. The process chamber 502, plasma source 501, or platen 503 may be grounded.

The sheath modifier 101 is used to focus ions 506 for implantation of a workpiece 100. This extraction of the plasma 140 from the plasma source 501 into the ions 506 may be continuous (DC) or pulsed. The plasma source 501 may be biased in one instance, Alternatively, an RF bias in the system 500 may or may not be pulsed. The sheath modifier 101 has at least one aperture 507, though multiple apertures 507 are possible. Adding more than one aperture 507 may increase throughput of the system 500. Thus, the sheath modifier 101 design is not limited solely to the design illustrated in FIG. 2.

One or more workpieces 100, which may be semiconductor wafers, are arranged on a platen 503 in the process chamber 502. The platen 503 may use electrostatic clamping, mechanical clamping, or a combination of electrostatic and mechanical clamping to retain the workpiece 100. The workpiece 100 may be scanned using the platen 503. In the embodiment of FIG. 2, the platen 503 can scan in the direction 505. The platen 503, however, may perform either 1D, 2D, or 3D scanning or rotation depending on the desired implant pattern on the workpiece 100. In an alternate embodiment, the sheath modifier 101 translates with respect to the workpiece 100. Various load and unload mechanisms may be used to place the workpiece 100 on the platen 503. The platen 503 may be configured to provide backside gas cooling to the workpiece 100 in one instance. The workpiece 100 may be heated or cooled to various temperatures before or during implantation using the platen 503 or some other apparatus.

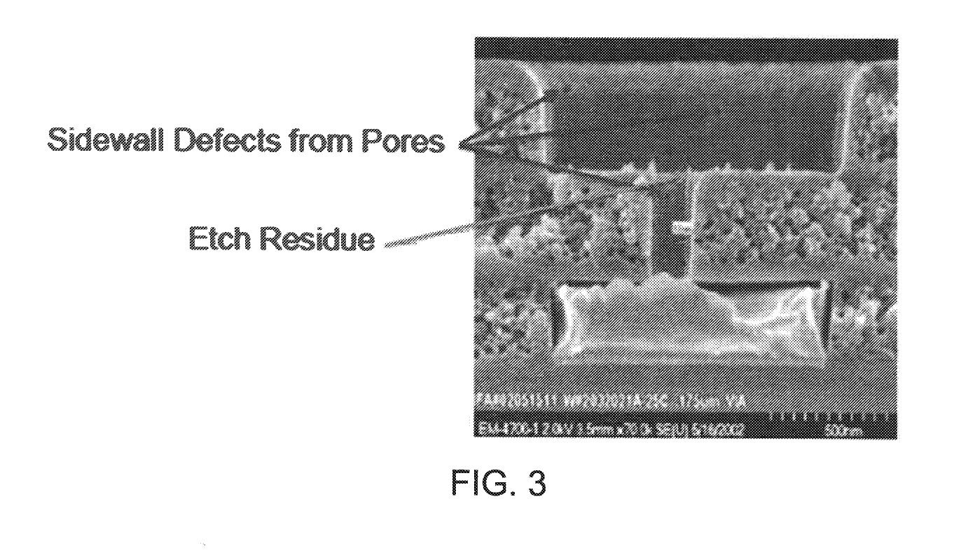

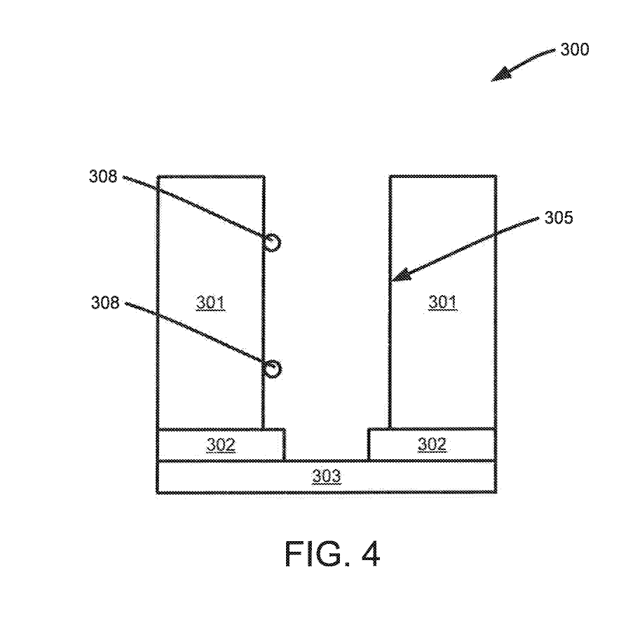

FIG. 3 is a SEM photograph of a first three-dimensional structure. Etch residue remains in the three-dimensional structure and there are sidewall defects from the pores. FIG. 4 is a cross-sectional diagram of a second three-dimensional structure. The structure 300, which may be part of the workpiece 100, includes a porous low-k material 301, such as SiCOH, though other materials may be used. The structure 300 also includes a dielectric barrier 302 and a copper layer 303. Water can enter the porous low-k material 301. The structure 300 also has material 308, which may be etch residue, on a sidewall 305. Variations of the structure 300 are possible and the embodiments herein are not merely limited to the structure 300.

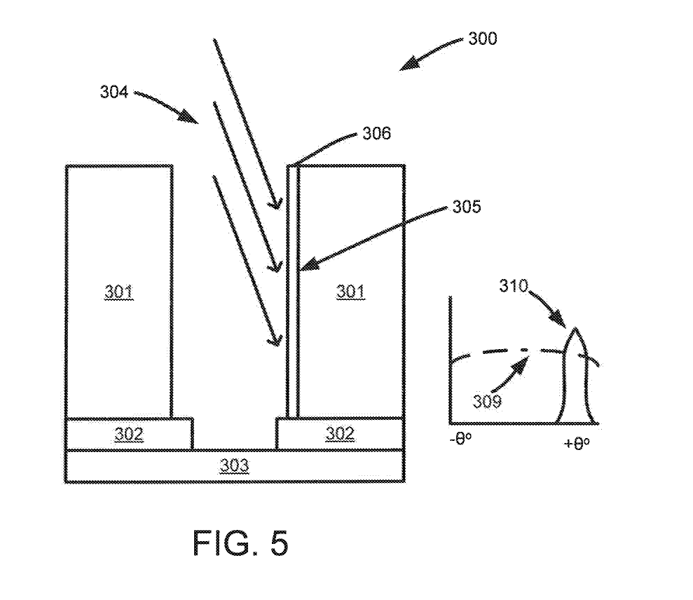

The embodiments herein may perform pore sealing on one sidewall, more than one sidewall, or all surfaces (including the bottom) of a structure. FIG. 5 illustrates a first embodiment of pore sealing. Ions 304, which may correspond to ions 506 or ions 102, are used to seal pores on a sidewall 305 and form sealing layer 306. In this embodiment, only one sidewall 305 is processed at a time. In this embodiment, the top of the structure 300 is impacted by ions 304. If the top of the structure 300 blocks enough of the ions 304, it may shadow the ions 304 such that not all of the sidewall 305 is processed. This shadowing effect depends on the angle of the ions 304 relative to the shape of the structure 300. Thus, the ions 304 either may be directed primarily at a particular angle (e.g., +60°) or may have an incident angle range but be shadowed by the structure 300. These two possibilities are illustrated in the angle distribution 309 (illustrated with the dotted line in FIG. 5) and angle distribution 310. Only one of the angle distribution 309 or angle distribution 310 may be used at once.

Multi-angle control of the ions 304, such as by modifying a plasma sheath as illustrated in, for example, FIGS. 1-2, enables the structure 300 to he processed as desired. The sidewall 305 of the structure 300 is amorphized or densified to a particular depth based on the energy and species of the ions 304. The sealing layer 306 may be formed using a low energy implant or plasma process in one instance. For example, an energy of approximately 100 eV to 750 eV may be used, though other energies are possible. The ions 304 may be inert ions, metal ions, reactive ions, carbon-containing ions, or combinations thereof. The inerts may be Ar, He, Ne, other noble gases, N, or H for example. The reactive ions may be CₓF_{y} or another halogen-containing species and the metal ions may be Ti or Cu. A combination of the ions 304 may be, for example, an inert used with CH₄ and C₂H₂, N₂ and H₂, Ar and H₂, or Ar and He. Of course, other species, combinations, or mixtures known to those skilled in the art may be used.

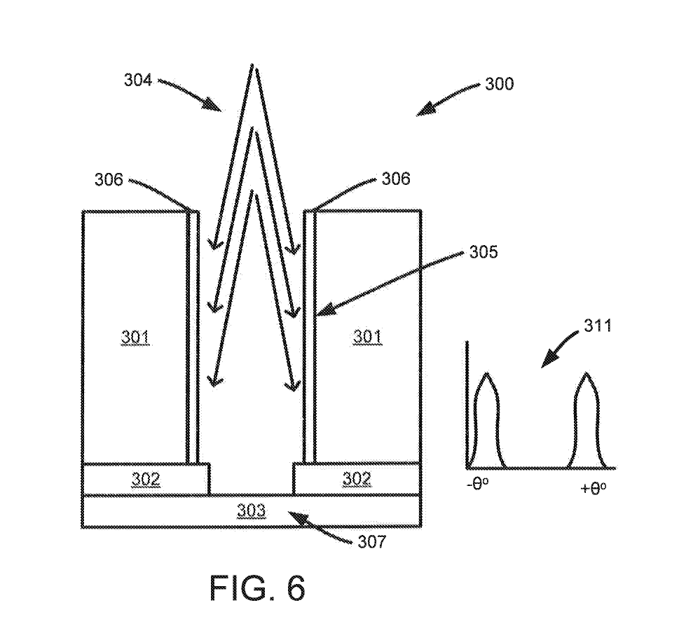

FIG. 6 illustrates a second embodiment of pore sealing. In this embodiment, the sealing layer 306 is formed on both sidewalls 306. This may be performed simultaneously by forming a spread of ions 304. The ions 304 may have a bimodal distribution in one example. In one instance, the distribution is not centered at 0° but instead is offset to +25° and −25° with a minimal amount of normal ions at 0°. This is illustrated in angle distribution 311. Thus, there are few or no ions 304 that implant the bottom 307 of the structure 300 because the spread of the ions 304 is controlled. To generate the ion distribution 311, in one embodiment the panels of the sheath modifier may be disposed at different distances from the surface of the workpiece (Z) containing the structure 300.

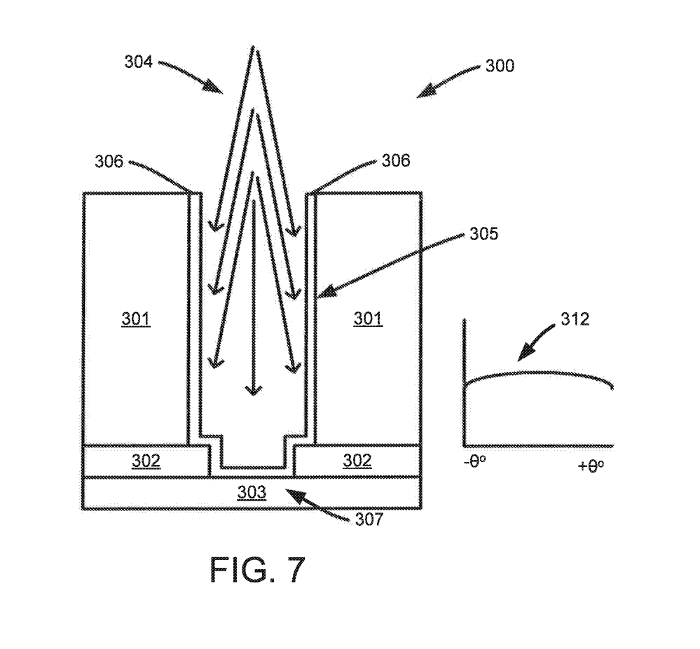

FIG. 7 illustrates a third embodiment of pore sealing. In this embodiment, the sealing layer 306 is formed on all surfaces of the structure 300 including the bottom 307. The ions 304 may be centered around 0° in this embodiment, as illustrated by ion distribution 312. Thus, the sealing layer 306 is formed on the dielectric barrier 302 and copper layer 303. In one instance, the sealing layer 306 has a uniform thickness. In another instance, the thickness on the sidewalls 305 or the bottom 307 is different. This may be performed by changing the relative weights of ions 304 in the spread or distribution so that more implant the sidewalls 305 than the bottom 307 or vice versa. The desired distribution of ions 304 may be at least partly based on the material makeup of the low-k material 301.

The pore sealing in the embodiments disclosed herein may physically close pores in the structure 300. These closed pores may be part of the sealing layer 306 in one instance. Thus, the sealing layer 306 may include additional material added to the structure 300, may be material modification of the structure 300, or may be a combination of these two. If additional material is added to the structure 300, it may close or fill any pores that are open. Material modification of the structure 300 may include, for example, mechanisms such as densification, deposition, amorphization, or sputter and redeposition. Any amorphization may be to a controlled depth. Enough energy may be provided using material modification that the pores mechanically close.

The particular angles of the ions 304 may be configured using, for example, the systems illustrated in FIGS. 1-2. Of course, other systems known to those skilled in the art also may be used. The systems of FIGS. 1-2 may enable low divergence of the ions 304 other than the desired angle spread. The particular angles or distribution of angles may be selected or controlled in these or other systems.

In an alternate embodiment, metal ions such as Ti, Cu, W, Al, Co, or other species are implanted into all or some of the sealing layer 306 or structure 300 after or partly during formation of the sealing layer 306. These metal ions may be used to form a dielectric-metal interface and serve as a nucleation layer or seed layer for a later-formed barrier metal in the structure 300. If the ions 304 contain the metal ions alone or with another species as part of a combination, then this may be performed in one step. The metal ions also may be implanted during a separate step.

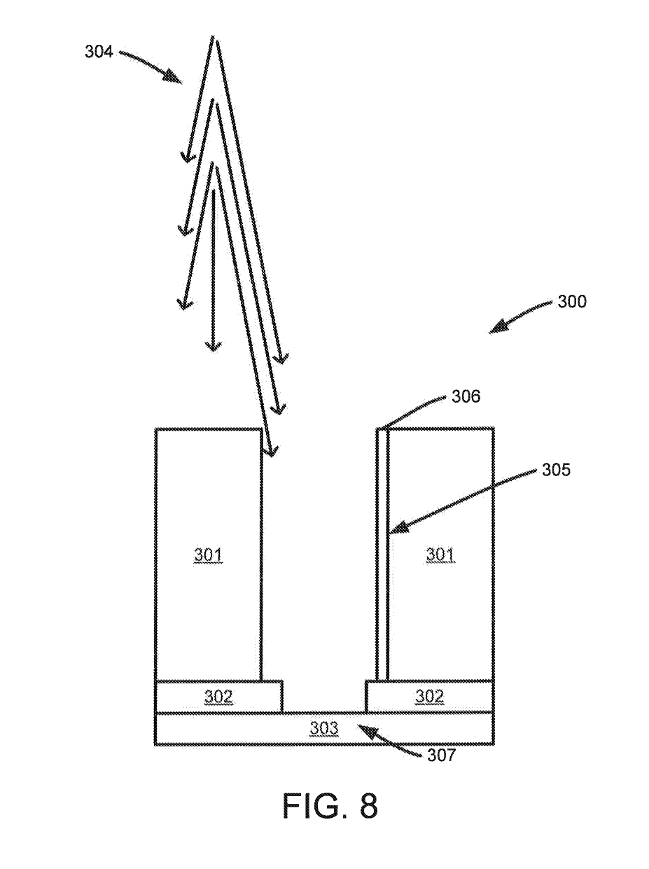

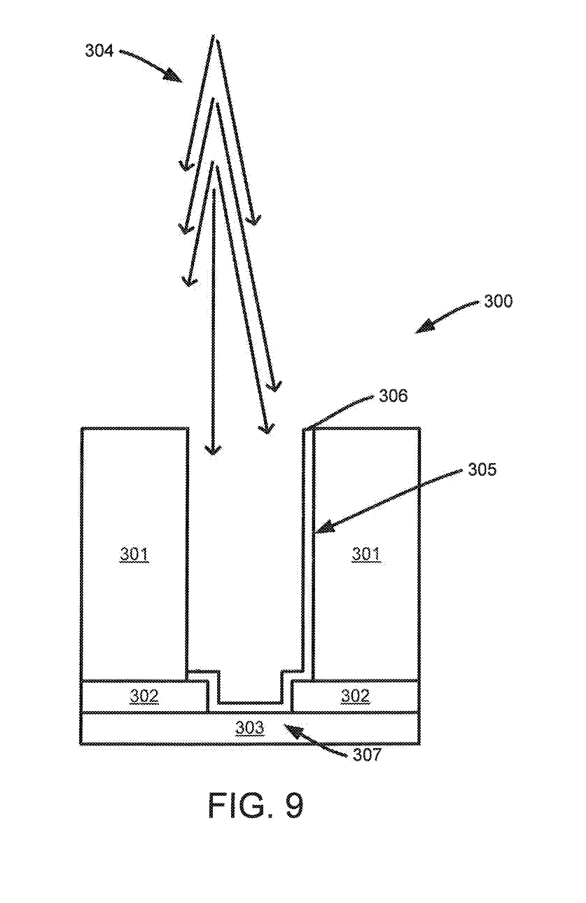

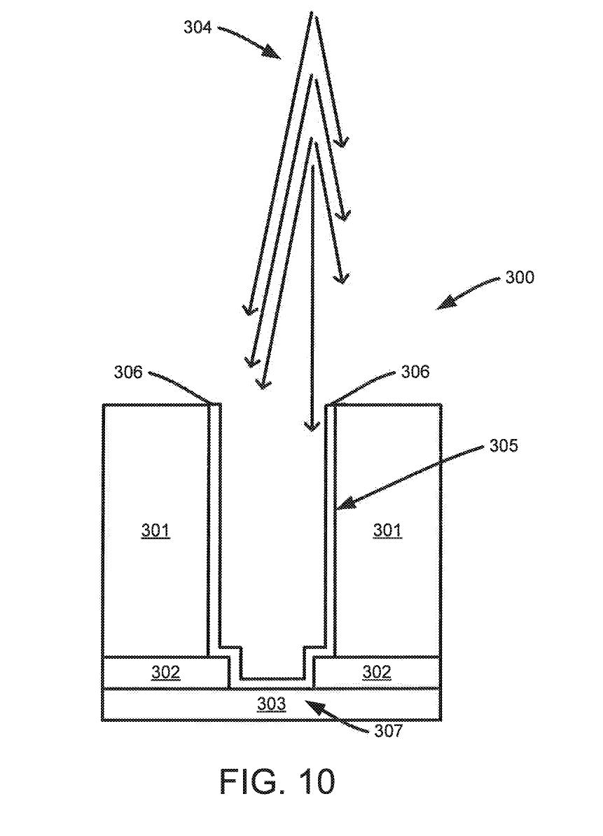

FIGS. 8-10 illustrate a fourth embodiment of pore sealing. In this embodiment, the structure 300 is scanned with respect to the ions 304. The ions 304 have an angle spread such that some of the ions 304 impact the structure 300 at non-perpendicular angles. In FIG. 8, only some of the ions 304 (illustrated with longer lines) reach the sidewalls 305 or bottom 307 of the structure 300. Thus, a sealing layer 306 is formed on or in only part of the structure 300. As the structure 300 and ions 304 are scanned with respect to each other, some of the ions 304 form a sealing layer 306 on the bottom 307 of the structure 300 as seen in FIG. 9. Then in FIG. 10, ions 304 form a sealing layer 306 on the other sidewall 305. In one example, the ions 304 have a range of incident angles between +60° and −60° centered about 0°. Initially one of the sidewall 305 sees angles at +60° but not −60°. Over the course of the scan the other sidewall 305 eventually sees angles at −60° but not +60°.

In one embodiment, the process illustrated in FIGS. 8-10 may be performed in a single scan or pass. In another embodiment, the process illustrated in FIGS. 8-10 may be performed with multiple scans or passes. The relative speed between the ions 304 and the structure 300 or the energy of the ions 304 may vary with each scan or pass.

Some species of ions 304 can repair or change the properties of the structure 300 in the sealing layer 306. Repair of damage or imperfections may include mechanisms such as amorphization, sputter and redeposition, or deposition. Certain ions 304 also can render the sealing layer 306 hydrophobic. In one instance, implanting a CF₂⁺ ion may render the sealing layer 306 hydrophobic. This may help prevent water from entering the low-k material 301. The species of ions 304 that are implanted may in part affect the hydrophobicity. Certain energy levels or doses during implantation may modify the structure 300, which also may in part affect the hydrophobicity. Other mechanisms that affect the hydrophobicity may be possible.

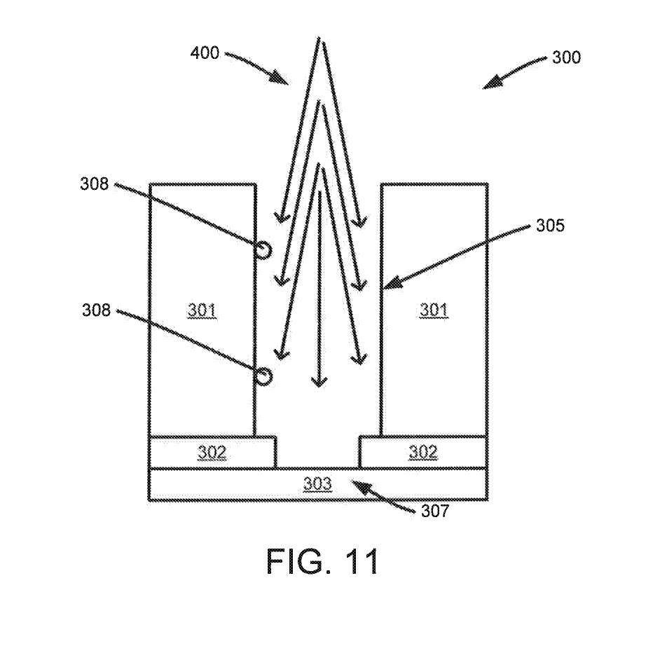

The ions also may remove any material, such as etch residue, that remains on the sidewall 305. FIG. 11 illustrates a first embodiment of cleaning. Material 308, which may be etch residue, is on one of the sidewalls 305. While only two pieces of material 308 are illustrated, in another embodiment the material 308 coats one or more surfaces of the structure 300.

A low energy treatment of ions 400, which may correspond to ions 506 or ions 102, into the structure 300 using an inert or reactive species may be used to perform this cleaning process. Systems such as those illustrated in FIGS. 1-2 may be used. This low energy treatment may be approximately 50 eV to 1.5 keV. In one particular example, the low energy treatment was performed at 750 eV. The ions 400 may be the same or different from the ions 304. This cleaning may entail either physical removal or chemical removal of the material 308. For example, a noble gas, H, mixture of a noble gas with H, or other species known to those skilled in the art may be used to form ions 400 that enable physical removal of any material 308. This physical removal may involve a sputtering mechanism. A halogen, a hydride molecule, a halide molecule, or other species known to those skilled in the art may be used to form ions 400 that enable chemical removal of any material 308. This chemical removal may involve an ion-assisted sputtering or etching mechanism. Combinations of the ions 400 may involve both physical removal with chemical removal of the material 308.

The angle control of the ions 400 may enable complete cleaning of the structure 300 because all surfaces may be impacted by the ions 400. However, the ions 400 may be of varying angle spreads. For example, the ions 400 may have a bimodal distribution to only or primarily clean the sidewalls 305. In another embodiment, only one sidewall 305 is cleaned or the bottom 307 of the structure 300 is cleaned using the ions 400.

The energy of the ions 400 is configured during cleaning to control the depth of removal of material 308. This energy may be configured to prevent damage to the sidewalls 305. In one instance, a sensor detects components of the structure 300 in the plasma containing the ions 400, which may signal that the cleaning process should stop. This energy also may be configured to prevent amorphization or densification of, for example, the low-k material 301. In one example, material on the sidewalls of a trench was removed using an approximately 750V Ar ion treatment. The material removed was approximately 6 nm thick.

In one embodiment, cleaning the structure may be performed using a process similar to that illustrated in FIGS. 8-10. One or more scans or passes may be used to clean the structure 300. The relative speed between the ions 400 and the structure 300 or the energy of the ions 400 may vary with each scan or pass.

The structure 300 may be cleaned before pore sealing occurs. This may use one or more different plasmas and may be performed as a chained process without breaking vacuum around the workpiece. Of course, these also may be separate steps where vacuum is broken around the workpiece between steps.

In one particular embodiment, a cleaning process is performed on the structure 300 prior to sealing pores in the structure 300. A first plasma is formed using a noble gas, a halogen, H, a hydride molecule, a halide molecule, or other species known to those skilled in the art. This first plasma is used to remove etch residue from one of the sidewalls 305 of the structure 300. A second plasma is then formed using a carbon-containing species, a noble gas, H, N, or other species known to those skilled in the art. This second plasma also may contain a metal. The second plasma is used to seal pores on one of the sidewalls 305 of the structure 300. This process also may be performed on multiple sidewalls 305 or the bottom 307 of the structure 300. While two different ions may be used in these steps, in another example a single plasma of a noble gas or H is used for both the cleaning and pore sealing processes. Various plasma parameters or the implant energy may be changed between the cleaning and pore sealing steps.

Pore sealing and cleaning also may be used to correct center-to-edge non-uniformity that was caused by etching the structure 300. In one instance, the dose of the ions may vary over the surface of the workpiece. Thus, the dose in the center of the workpiece may be different from the dose on the edges of the workpiece to compensate for any such non-uniformities.

For either pore sealing or cleaning, if the structure 300 has four sidewalls, the workpiece containing the structure 300 may be rotated with respect to the ions. For example, the workpiece may be rotated 90° with respect to the ions. This will allow the ions 304 or ions 400 to impact all four sidewalls of such a structure. Three 90° rotations may be used or rotations up to a full 360° may be used. Different ion distributions may be used at different steps if the workpiece is rotated. Of course, the ion angle distribution may be configured to impact all four sidewalls of the structure 300 without rotation. The ions may be extracted to have angle distributions across both dimensions of the surface of the workpiece.

The pulse during formation of the ions 304 or ions 400 also may affect pore sealing or cleaning. For example, at the beginning of the pulse the ions 304 or ions 400 may all be parallel to the bottom 307 of the structure 300. Later during the pulse, a wider angle spread of the ions 304 or ions 400 may be formed. This may enable treatment of the sidewalls 305 and bottom 307 of the structure 300.

The embodiments disclosed herein can be applied to many different kinds of structures 300 and are not limited just to the structure 300 illustrated herein. For example, these embodiments can be applied to 3D semiconductor structures such as finFETs or trenches, magnetoresistive random-access memory (MRAM) structures, solar structures, microelectromechanical systems (MEMS) structures, or other structures known to those skilled in the art.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. These other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of workpiece processing comprising:
generating a plasma having a plasma sheath proximate a surface of said workpiece, wherein said workpiece defines a structure with a plurality of sidewalls;
controlling a shape of a boundary between said plasma and said plasma sheath whereby a portion of said shape is not parallel to a plane defined by a front surface of said workpiece facing said plasma;
directing ions in said plasma toward said workpiece; and
sealing pores on one of said sidewalls with said ions.

2. The method of claim 1, further comprising sealing pores on another of said sidewalls of said structure with said ions.

3. The method of claim 2, wherein said structure is a trench that also defines a bottom and further comprising sealing pores on said bottom of said structure with said ions.

4. The method of claim 3, further comprising scanning said workpiece with respect to said ions during at least one pass.

5. The method of claim 4, wherein said scanning comprises at least two of said passes and each of said passes has a different speed.

6. The method of claim 4, wherein said sealing pores occurs on said one of said sidewalls before said bottom and said sealing pores occurs on said bottom before said another of said sidewalls during said scanning.

7. The method of claim 2, wherein said ions have a bimodal distribution.

8. The method of claim 1, wherein said ions comprise a metal.

9. The method of claim 1, wherein said ions form a sealing layer on said structure and said sealing layer is configured to be hydrophobic.

10. The method of claim 1, wherein said ions comprise at least one of a carbon-containing species, hydrogen, nitrogen, or a noble gas.

11. A method of workpiece processing comprising:
generating a plasma having a plasma sheath proximate a surface of said workpiece, wherein said workpiece defines a structure with a plurality of sidewalls;
controlling a shape of a boundary between said plasma and said plasma sheath whereby a portion of said shape is not parallel to a plane defined by a front surface of said workpiece facing said plasma;
directing ions in said plasma toward said workpiece; and
removing a material from one of said sidewalls of said structure with said ions.

12. The method of claim 11, further comprising removing said material from another of said sidewalls of said structure with said ions.

13. The method of claim 12, wherein said structure is a trench that also defines a bottom and further comprising removing said material from said bottom of said structure with said ions.

14. The method of claim 13, further comprising scanning said workpiece with respect to said ions in at least one pass.

15. The method of claim 14, wherein said scanning comprises at least two of said passes and said ions have a different energy during each of said passes.

16. The method of claim 14, wherein said removing occurs on said one of said sidewalls before said bottom and said removing occurs on said bottom before said another of said sidewalls during said scanning.

17. The method of claim 12, wherein said ions have a bimodal distribution.

18. The method of claim 11, wherein said ions comprise at least one of a noble gas, a halogen, hydrogen, a hydride molecule, or a halide molecule.

19. The method of claim 11, wherein said material comprises etch residue.

20. A method of workpiece processing comprising:
generating a first plasma having a first plasma sheath proximate a surface of said workpiece, wherein said workpiece defines a trench with a plurality of sidewalls;
controlling a first shape of a first boundary between said first plasma and said first plasma sheath whereby a portion of said first shape is not parallel to a plane defined by a front surface of said workpiece facing said first plasma;
directing first ions in said first plasma toward said workpiece;
removing etch residue from one of said sidewalls of said trench with said first ions;
generating a second plasma having a second plasma sheath proximate said surface;
controlling a second shape of a second boundary between said second plasma and said second plasma sheath whereby a portion of said second shape is not parallel to said plane;
directing second ions in said second plasma toward said workpiece; and
sealing pores on one of said sidewalls with said second ions.

21. The method of claim 20, wherein said first ions comprise at least one of a noble gas, a halogen, hydrogen, a hydride molecule, or a halide molecule and said second ions comprise at least one of a carbon-containing species, a noble gas, hydrogen, nitrogen, or a metal.

22. The method of claim 20, wherein said first ions and said second ions comprise a noble gas and wherein said first plasma is said second plasma.

23. The method of claim 20, wherein a vacuum is formed around said workpiece prior to generating said first plasma and said vacuum is maintained through said sealing.
